(19) United States
(12) Patent Application Publication
(10) Pub. No.: US 2004/0050327 A1
(43) Pub. Date: Mar. 18, 2004

(54) Vertically translatable chuck assembly and method for a plasma reactor system

(75) Inventors: Wayne L. Johnson, Phoenix, AZ (US); Steven T. Fink, Mesa, AZ (US); Jeff Browning, Maricopa, AZ (US); Jovan Jevtic, Milwaukee, WI (US)

Correspondence Address: PILLSBURY WINTHROP, LLP, P.O. BOX 10500, MCLEAN, VA, 22102, US

(73) Assignee: Tokyo Electron Limited, Tokyo (JP)

(21) Appl. No.: 10/621,464

(22) Filed: Jul. 18, 2003

Related U.S. Application Data
(63) Continuation of application No. PCT/US01/48851, filed on Dec. 20, 2001.
(60) Provisional application No. 60/262,642, filed on Jan. 22, 2001.

(51) Int. Cl. C23C 14/00; B05C 9/08; C23C 16/00

(52) U.S. Cl. 118/715; 118/620; 118/640; 118/50.1

(57) ABSTRACT

A chuck assembly for supporting a workpiece within a plasma reactor chamber having sidewalls surrounding an interior region capable of supporting a plasma. The assembly includes a chuck base and at least one support arm extending outwardly from the chuck base perimeter to the chamber sidewalls. The chuck assembly includes a workpiece support member which is supported by one or more vertical translation members arranged between and operatively connected to the chuck base and the workpiece support member.

This is a Continuation application of International Application No. PCT/US01/48851, filed on Dec. 21, 2001, which, in turn, claims the benefit of Provisional U.S. Patent Application No. 60/262,642, filed Jan. 22, 2001, the contents of both of which are incorporated herein in their entirety.

### BACKGROUND OF THE INVENTION

1. Field of the Invention

The present invention relates to plasma reactor systems, and in particular relates to chucks for plasma reactor systems.

2. Background Of The Invention

Ionized gas or “plasma” may be used during processing and fabrication of semiconductor devices, flat panel displays and other products requiring etching or deposition of materials. Plasma may be used to etch or remove material from semiconductor integrated circuit wafers, or sputter or deposit material onto a semiconducting, conducting or insulating surface. Creating a plasma for use in manufacturing or fabrication processes typically is done by introducing a low-pressure process gas into a chamber surrounding a workpiece such as an integrated circuit (IC) wafer that resides on a workpiece support member, more commonly referred to as a “chuck.” The molecules of the low-pressure gas in the chamber are ionized into a plasma by a radio frequency energy (power) source after the gas molecules enter the chamber. The plasma then flows over and interacts with the workpiece, which is typically biased by providing RF power to the chuck supporting the workpiece. In this regard, the chuck serves as an electrode, and is thus sometimes referred to as a “chuck electrode.” The plasma gas flowing over the chuck is removed by a vacuum system connected to the chamber.

One of the key factors that determine the yield and overall quality of an IC is the uniformity of the plasma process at the surface of the workpiece. In plasma reactors, the process uniformity is governed by the design of the overall system, and in particular by the physical relationship of the chuck, plasma generation source, radio frequency (RF) tuning electronics, and vacuum pumping system.

The plasma chamber is maintained at the low pressure required for plasma formation through the operation of the aforementioned vacuum pump (e.g., a turbo-mechanical pump) that is in pneumatic communication with the chamber. Conventional plasma reactor system designs have the connection to the vacuum pump provided on the side of the reactor chamber.

U.S. Pat. No. 5,948,704 (“the '704 patent”) discloses a plasma chamber with a chuck connected by a support arm to the side of the chamber in a cantilever fashion. A gas distribution plate issues gas into the chamber and a vacuum pump removes gas along an axis perpendicular to the chuck.

In certain plasma reactor systems, it is beneficial to provide an axially (i.e., vertically) translatable chuck. This allows for the workpiece to be exposed to different regions of the plasma gas, which results in the workpiece being processed differently.

To obtain fast plasma processing of a workpiece, it is necessary to deliver a large amount of RF power to the chuck. To do so, a low-impedance RF circuit is required to efficiently couple the RF power to the chuck. The RF circuit includes an impedance match network and an RF transmission line or stub, which connects the output of the match network to the chuck electrode. The impedance match network maximizes the power transferred to the plasma by matching the output impedance of the match network to that of the load, i.e., the match network impedance becomes the complex conjugate of the load impedance. In turn, the load impedance includes the impedance of the transmission line residing between the output of the match network and the chuck electrode, the chuck electrode itself, and the plasma formed adjacent the chuck.

### BRIEF SUMMARY OF THE INVENTION

The present invention relates to plasma reactor systems, and in particular relates to chucks for high-flow, high-power plasma reactor systems.

A first aspect of the invention is a chuck assembly capable of vertical translation for supporting a workpiece at different positions within a plasma reactor chamber having an interior region capable of supporting a plasma. The assembly includes a chuck base and at least one support arm extending outwardly from the chuck base perimeter to the chamber sidewalls. The support arm is adapted to support the chuck base within the interior region, while also adapted to provide a path for mechanical, electrical, pneumatic and/or fluid communication with the chuck assembly from outside the chamber. The chuck assembly further includes a workpiece support member, arranged above the chuck base, capable of supporting the workpiece. The workpiece support member is connected to an RF power supply and serves as a chuck electrode. The workpiece support member is supported above the chuck base by one or more vertical translation members arranged between and operatively connecting the chuck base and the workpiece support member. The chuck assembly includes a match network wherein at least a portion of the match network is mounted directly to the workpiece support member, thereby providing a low-impedance path from the RF power supply to the workpiece support member. The match network is designed so that most, if not all, of the match network elements (e.g., variable capacitors and one or more inductors) fit within the chuck assembly itself. Those elements not within the chuck assembly are housed outside of the assembly, and communicate with the other elements via an electrical connection through the support arm. The use of the support arm also allows for the positioning of a vacuum pump system directly beneath the chuck assembly.

A second aspect of the invention is a plasma reactor system for processing a workpiece. The system comprises a plasma reactor chamber having a central axis and sidewalls surrounding an interior region capable of supporting a plasma in an upper part of the interior region. The system includes the chuck assembly described briefly above arranged adjacent the upper part of the interior region and along the central axis. Also included in the system is a vacuum pump system arranged adjacent the chuck assembly opposite the upper part and along the central axis.

A third aspect of the invention is a method of providing for uniform, substantially axially symmetric flow of plasma gas over a workpiece in a plasma reactor chamber having a central axis and capable of containing a plasma in an upper interior region of the chamber. The method includes the step of supporting a chuck assembly within the reactor chamber with at least one support arm. The support arm is arranged such that gas can flow around the chuck assembly from the upper interior region. The next step includes arranging a vacuum pump system along the central axis adjacent the chuck assembly opposite the upper interior region. The next step involves providing the workpiece to the chuck assembly such that the workpiece is supported adjacent the upper interior region. The next step involves flowing a plasma-forming gas into the upper interior region and forming a plasma in the upper interior region. The next step is then activating the vacuum pump system so as to draw gas from the upper interior region over the workpiece and into the vacuum pump system residing directly beneath the chuck assembly.

### BRIEF DESCRIPTION OF SEVERAL VIEWS OF THE DRAWING

FIG. 1A is a schematic cross-sectional diagram of the plasma reactor system according to one embodiment of the present invention illustrating its various components and showing one of the three support arms that support the chuck assembly within the reactor chamber;

FIG. 1B is a schematic cross-sectional diagram of the plasma reactor system according to another embodiment of the present invention illustrating its various components and showing one of the three support arms that support the chuck assembly within the reactor chamber;

FIG. 1C is a schematic cross-sectional diagram of the plasma reactor system according to another embodiment of the present invention illustrating its various components and showing one of the three support arms that support the chuck assembly within the reactor chamber;

FIG. 2 is a plan view of the chuck assembly of FIGS. 1A-C with just the chuck base and support arms present, and also showing the systems connected to the chuck base via the support arms, along with the workpiece load chamber;

FIG. 3 is a schematic cross-sectional view of a portion of the plasma reactor system of FIG. 1 showing the RF power supply and cooling support arm and the elements making up a first embodiment of a chuck RF supply system, and the cooling system;

FIG. 4 is a schematic circuit diagram of the L-type match network of FIG. 3;

FIG. 5 is a schematic cross-sectional view of a portion of the plasma reactor system similar to that of FIG. 3, but showing a second embodiment of a chuck RF supply system;

FIG. 6 is a schematic cross-sectional view of a portion of the plasma reactor system of FIGS. 1A-C showing the utilities support arm and the elements making up the utility supply system of the present invention; and

FIG. 7 is a schematic cross-sectional view of a portion of the plasma reactor system of FIGS. 1A-C, showing the mechanical support arm and an embodiment of the vertical translation mechanism of the present invention.

### DETAILED DESCRIPTION OF SEVERAL EMBODIMENTS OF THE INVENTION

The present invention relates to plasma reactor systems, and in particular relates to chucks for high-flow, high-power plasma reactor systems.

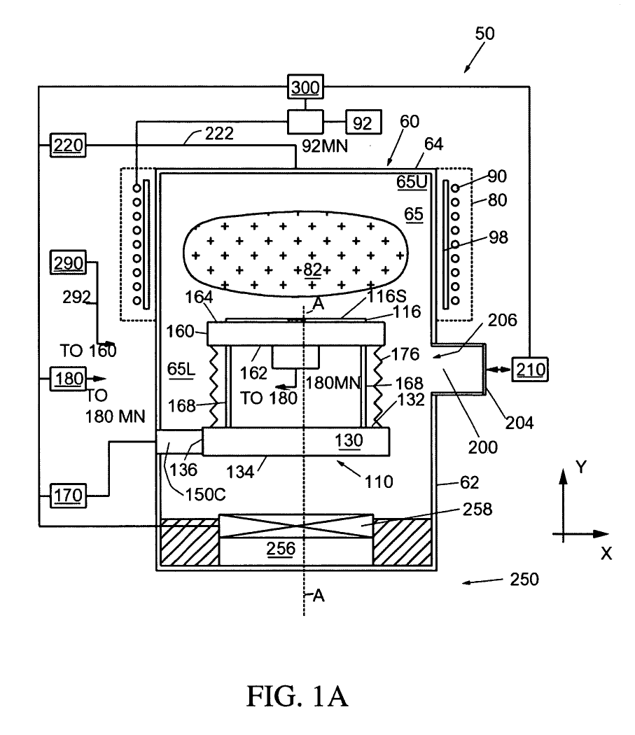

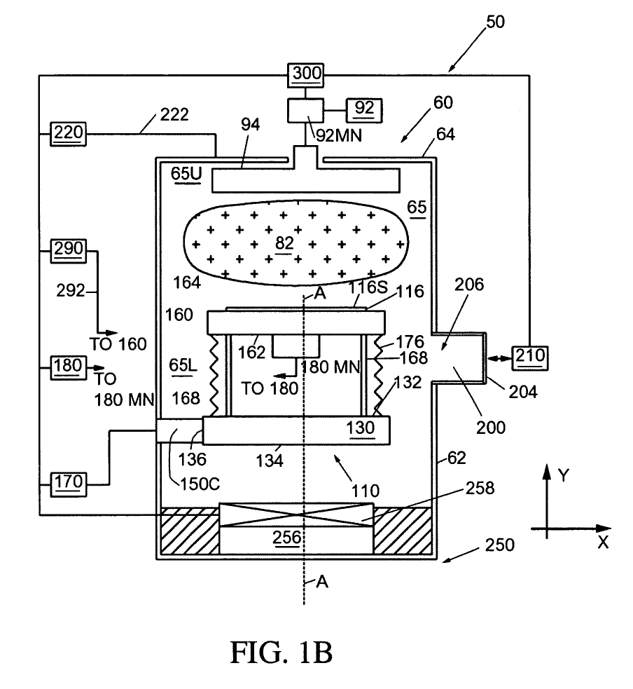

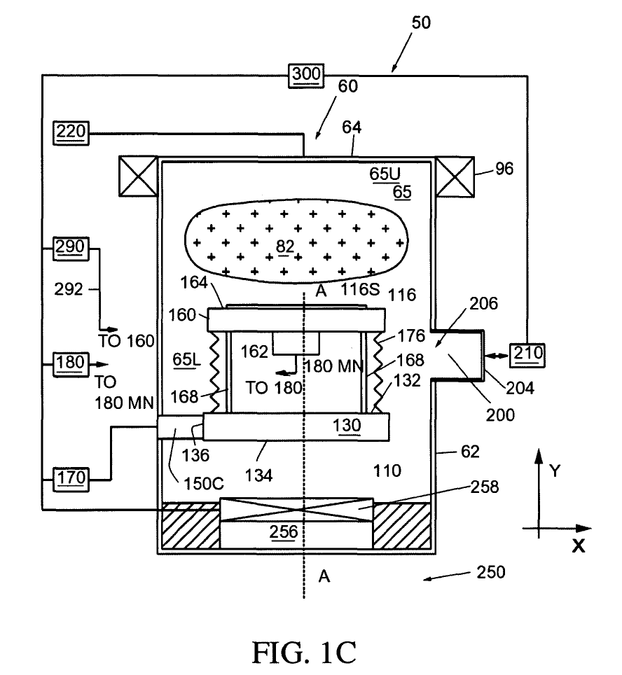

With reference to FIG. 1A, there is shown a plasma processing system 50 that includes a plasma chamber 60 having an outer wall 62 and an upper wall 64 that encloses an interior region 65 that includes an upper interior region (or “upper part”) 65U closest to the upper wall, and a lower interior region (or “lower part”) 65L adjacent the upper region. Surrounding chamber 60 about upper region 65U is a plasma source generator 80 capable of igniting and sustaining a plasma 82 in upper region 65U of chamber 60.

Plasma processing system 50 may be any one of a number of plasma processing systems, such as an electrostatically shielded radio frequency (ESRF) plasma system, as shown in FIG. 1A. Such plasma processing systems are described in U.S. Pat. No. 4,938,031 and 5,234,529, which patents are incorporated herein by reference. Thus, in an exemplary embodiment of system 50, plasma source generator 80 includes an inductive coil 90 that encircles a portion of chamber 60 so as to surround upper region 65U. Inductive coil 90 may be a helical resonator (i.e. a quarter-wave or half-wave resonator), wherein one coil end is grounded, and the opposite coil end is open. Coil 90 is tapped near the grounded end, whereby the coil is electrically connected to an RF power supply 92 through a match network 92MN. The latter is used to maximize RF power transfer to plasma 82. Between inductive coil 90 and chamber wall 62 is a grounded electrostatic shield 98 (also referred to as an E-shield or Faraday shield) comprising an electrically grounded, conductive sheet with slots (not shown) aligned parallel with the axis of revolution A (i.e., the central axis) of chamber 60 (i.e., in the vertical or Y-direction) and are typically equally spaced. E-shield 98 minimizes capacitive coupling between coil 90 and plasma 82 by limiting the area through which the electromagnetic field from the coil can couple to the plasma. Furthermore, the wall 64 additionally includes a dielectric window (not shown) proximate the inductive coil 90 in order to allow the penetration of the RF electromagnetic field into the plasma. Other plasma source configurations can include capacitively coupled plasma (CCP) sources, electron cyclotron resonance (ECR) plasma sources, helicon-type plasma sources, etc., without limiting the scope of the present invention.

For example, in another embodiment according to the present invention, FIG. 1B presents a plasma reactor system 50 comprising an upper electrode 94 electrically coupled to RF power supply 92 through match network 92MN. Capacitively coupled plasma reactors are well known to those of skill in the art.

Additionally, in another embodiment according to the present invention, FIG. 1C presents a plasma reactor system 50 comprising a grounded wall 64. In an alternate embodiment, plasma reactor system 50 can further comprises either a stationary or rotating ring of magnets 96. Reactive ion plasma reactor systems and their design is well known to those of skill in the art.

With reference to FIGS. 1A-C and 2, chamber 60 further includes a chuck assembly 110 located within chamber 60 in lower interior region 65L, for supporting a workpiece (e.g., a wafer) 116 having an upper surface 116S. Chuck assembly 110 includes a chuck base 130 having an upper surface 132, a lower surface 134 and a perimeter 136. Chuck 110 is suspended within lower interior region 65L by three support arms 150A-150C that connect to the perimeter of chuck base 130 and that are attached to outer wall 62. Support arms 150A-150C are adapted to provide a path for connecting RF power, utilities and mechanical power to chuck assembly 110. In particular, and as discussed in greater detail below, support arm 150A serves as a RF network and cooling support arm, support arm 150B serves as a utilities support arm, and support arm 150C serves as a mechanical support arm. Although three support arms 150A-C are discussed, there can be either more or less.

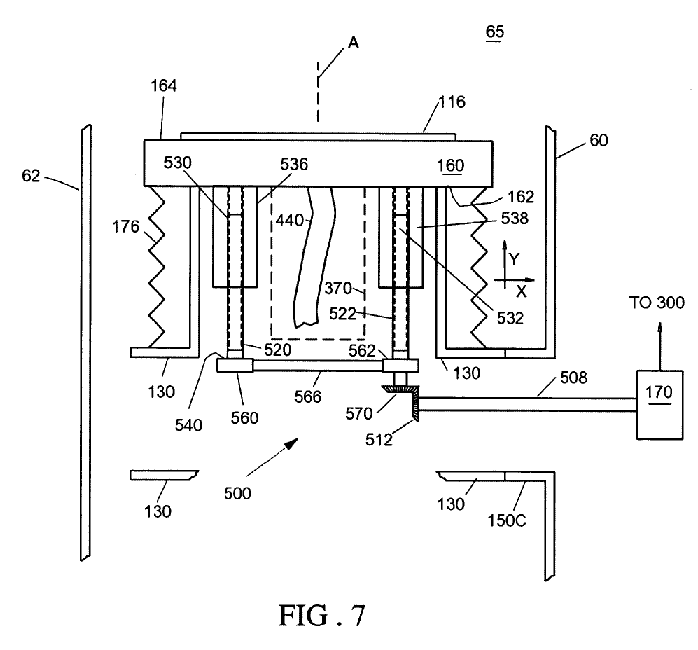

Chuck assembly 110 further includes a workpiece support member 160 having a lower surface 162 and an upper surface 164, with the upper surface directly supporting workpiece 116. The body of workpiece support member 160 includes one or more cavities 160C (not shown in FIG. 1) through which cooling fluid can flow to cool the support member and workpiece 116. Workpiece support member 160 is movably supported above chuck base upper surface 132 by one or more vertical translation members 168 arranged between and operatively connected to chuck base 130 and workpiece support member 160. In alternate embodiments, workpiece support member 160 can be removably mounted and workpiece support members can be configured to accomodate different sized workpieces. Vertical translation members 168 are further operatively connected to a vertical drive motor 170 external to chamber 60. An exemplary mechanism for vertically translating workpiece support member 160 relative to chuck base 130 is discussed further below with reference to FIG. 7. Chuck assembly 110 also preferably includes a bellows 176 connected at one end to lower surface 162 of workpiece support member 160, and at the opposite end upper surface 132 of chuck base 130. Bellows 176 is preferably made from stainless steel and serves to protect the rest of chuck assembly 110 from exposure to gas from plasma 82 as well as maintain the vacuum integrity of chamber 60. In alternate embodiments, chuck assembly 110 can be removably mounted within chamber 60 and chuck assembly 110 can easily be configured to accommodate different sized workpieces.

With continuing reference to FIGS. 1A-C, system 50 further includes a chuck RF power supply 180 for supplying RF power to workpiece support member 160, which also serves as an electrode. A chuck match network 180MN is provided, in whole or in part, immediately adjacent lower surface 162 of workpiece support member 160 so as to provide an impedance match to the load presented by plasma 82. This arrangement reduces the RF transmission line and is designed to reduce the load impedance and therefore increase the ion current flowing to workpiece 116. A more detailed description of embodiments for chuck match network 180MN is provided below.

System 50 further includes a workpiece load chamber 200 having a sealable door 204, attached to plasma chamber 60 near chuck assembly 110. Chamber 200 is in communication with lower interior region 65L through an aperture 206 in wall 62. Door 204 is sized to allow workpieces to be placed into workpiece load chamber 200. Also included is a workpiece handling system 210 in operable communication with load chamber 200 for transporting wafers to and from workpiece support member 160 through the load chamber.

Further included in system 50 is a gas supply delivery system 220, pneumatically connected to upper interior region 65U of chamber 60 via a gas line 222, for delivering a gas (e.g., Argon) for the formation of plasma 82.

System 50 also includes a vacuum pump system 250 arranged beneath lower surface 134 of chuck base 130 along central axis A. Vacuum pump system 250 includes vacuum pump 256, such as a turbo-mechanical pump of the kind typically used in plasma reactor systems, and a gate valve 258 arranged between chuck base 130 and the vacuum pump for controlling the vacuum level in interior region 65. Vacuum pump system 250 can include a roughing pump (not shown) connected to vacuum pump 256 and chamber 60 for initially pumping down chamber interior region 65. Gate valve 258 can be electromechanical so that it can be remotely operated via an electrical signal from a controller. Vacuum pump system 250 and gas supply system 220 together are capable of reducing the pressure in chamber 60 to between approximately 1 mTorr and approximately 1 Torr, depending on the application. The location of vacuum pump system 250 directly underneath chuck assembly 110 in the present invention is made possible by support arms 150A-150C, and serves to make the flow of gas axially symmetric, or substantially so.

Also included in system 50 is a cooling system 290 fluidly connected, via cooling lines 292, to chuck assembly 100 and cavities 160C in workpiece support member 160, for cooling the workpiece support member and workpiece 116 during plasma processing of the workpiece.

System 50 also includes a main control system 300 electronically connected to RF power supply 92 and match network 92MN, chuck RF power supply 180 and match network 180MN, vertical drive system 170, workpiece handling system 210, gas supply delivery system 220, vacuum pump system 250, and cooling system 290. Control system 300 controls and coordinates the operation of the above-mentioned systems through respective electronic signals.

In operation, system 300 initiates the placement of workpiece 116 onto upper surface 164 of workpiece support member 160 through load chamber 200 via workpiece handling system 210. Control system 300 then activates vacuum pump system 250 to pump down interior region 65. Once the pressure of interior region 65 is reduced to a certain level (e.g., 10⁻⁸ to 10⁻⁴ Torr), control system 300 initiates the flow of gas from gas supply system 290 into upper region 65U. At about the same time, control system 300 activates RF power supply 92 to activate plasma source generator 80, thereby forming plasma 82 in upper region 65U adjacent workpiece 116. Control system 300 then activates chuck RF power supply 180 to bias workpiece support member 160, thereby initiating the flow of plasma towards workpiece upper surface 116S. Because chuck assembly 110 is suspended within interior region 65 with support arms 150A-150C, and because of the location of vacuum pump system 250, the plasma gas flows towards and over the wafer, around chuck assembly 110 and into vacuum pump 256 in a substantially axially symmetric manner.

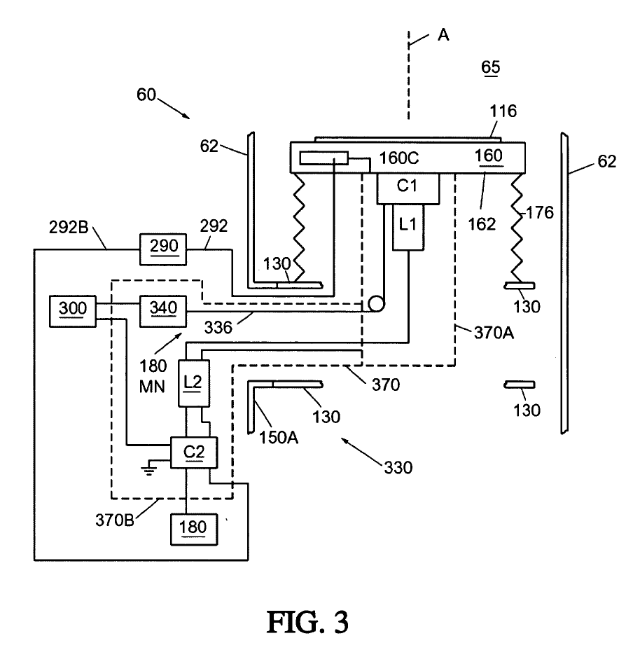

With reference now to FIG. 3, a more detailed description of chuck match network 180MN as part of a chuck RF supply system 330 and chuck assembly 110 is now provided in connection with support arm 150A. Support arm 150A is hollow so that it can serve as a conduit for supplying the RF power and cooling fluid to the chuck assembly.

A first embodiment of a chuck RF supply system of the present invention is system 330 of FIG. 3, which includes a first variable capacitor C1 mounted to lower surface 162 of workpiece support member 160 so as to be in direct electrical contact therewith. Electrically connected to variable capacitor C1 by means of a first capacitor lanyard 336 is a first capacitor servo 340 for adjusting the capacitance of variable capacitor C1. The capacitance of variable capacitor C1 is adjustable from about 100 to about 500 pF. First capacitor servo 340 is electrically connected to and is controlled by main control system 300. First capacitor lanyard 336 is designed to accommodate the vertical movement of first variable capacitor C1 when workpiece support member 160 is vertically translated.

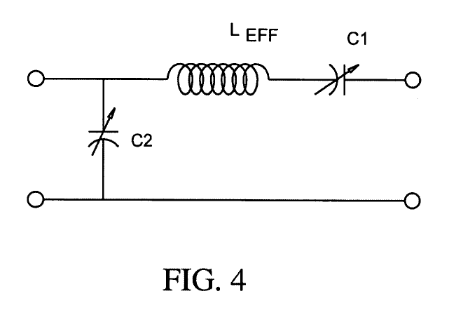

System 330 further includes a first inductor L1 located immediately adjacent variable capacitor C1 and electrically connected thereto. First inductor L1 is thus proximate lower surface 162 of workpiece support member 160. System 330 further includes a second inductor L2 in series with the first inductor but external (i.e., not proximate) to chuck assembly 100, and a second variable capacitor C2 external (i.e., not proximate) to the chuck assembly and arranged in parallel with the first and second inductors. For most applications, the values of first inductor L1 and second inductor L2 typically comprise a total inductance of about 400 nH with usually a 4-turn inductor internal to the chuck assembly (L1) and a 5-turn inductor external to the chuck assembly (L2), and the value of a second variable capacitor C2 typically ranges from 500 to about 1500 pF. The topology of chuck match network 180MN is L-type, and is illustrated in the circuit diagram of FIG. 4, with L_{EFF} being the effective inductance of the arrangement of inductors L1 and L2. Other topologies for the chuck match network, such as a T-network or a π-network, may be employed.

System 330 also includes RF power supply 180 connected across second variable capacitor C2. The reason for having two inductors, internal inductor L1 and external conductor L2, for locating second variable capacitor C2 external to chuck assembly 100, and for using lanyard 336 for adjusting the internal capacitor C1 is because of space limitations within chuck assembly 110.

As mentioned above, because match network 180MN (or at least a portion thereof) is located immediately adjacent workpiece support member 160, the need for a transmission line that connects the match network to the support member is eliminated. Accordingly, match network 180MN can be tuned by selecting the inductance values for the inductor(s) and varying the capacitance of the variable capacitors so as to provide a low impedance path from RF source 180 to workpiece support member 160.

Also optionally included in system 330 is a housing 370 that partly resides within chuck assembly 110 that encloses match network 180MN (370A), partly resides outside the chuck assembly 110 that encloses the outer portion of match network 180MN (370B), and that may also enclose a portion of cooling lines 292.

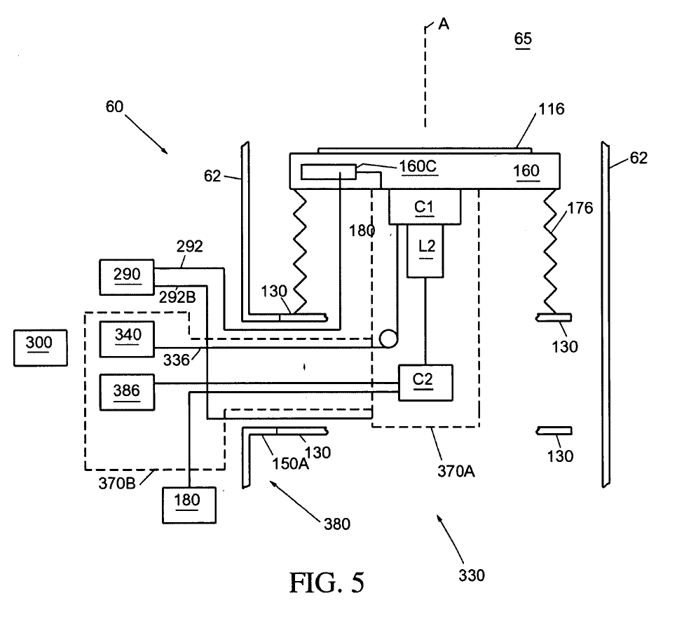

With reference now to FIG. 5, a chuck RF supply system 380 as an alternative embodiment to system 330 is now described. System 380 is similar to system 330 and has many of the same elements, except that in system 380, there is a single inductor L2′ in the position of inductor L2 of system 330, and second variable capacitor C2 is arranged internal to chuck assembly 100 rather than external. Second variable capacitor C2 is thus proximate workpiece support member lower surface 162, and is adjusted by an externally located second capacitor servo 386 electrically connected thereto, and also electrically connected to main control system 300. The electrical connection between capacitor servo 386 and second capacitor C2 may be by lanyard, such as lanyard 336, if the second capacitor is situated such that it moves along with workpiece support member 160. Where there is adequate room in chuck assembly 110, capacitor servos 340 and 386 may be moved into the chuck assembly, thereby eliminating the need for lanyards. Housing 370 comprised of components 370A and 370B may also be used to enclose all or part of system 380.

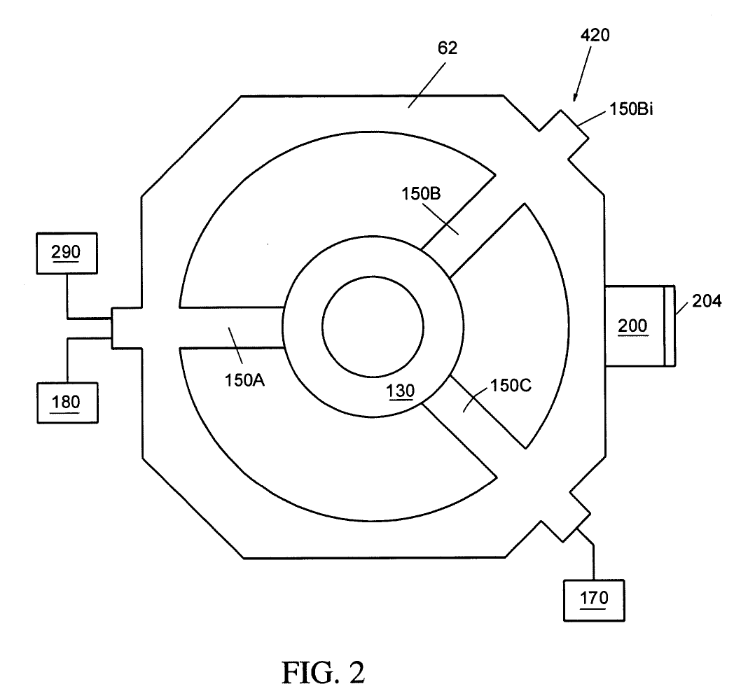

With reference again to FIGS. 1 to 3, support arm 150A serves as a conduit for cooling inlet line 292 and coolant outlet line 292B that fluidly connect cooling system 290 to workpiece support member cavities 160C, inner match network 180MN cavity within housing 370A (for external cooling of variable capacitor C1 and inductor L1 which are immersed within the coolant contained in 370A as shown in FIG. 3, or additionally variable capacitor C2 as shown in FIG. 5), the interior of inductor L2 as shown in FIG. 3 (inductor coil L2 can be fabricated from hollow copper tubing) and a (copper) cooling manifold on variable capacitor C2 as shown in FIG. 3. Cooling system flows cooling fluid to and from cavities 160C via cooling lines 292 so that fluid can be circulated through workpiece support member 160 during the processing of workpiece 116.

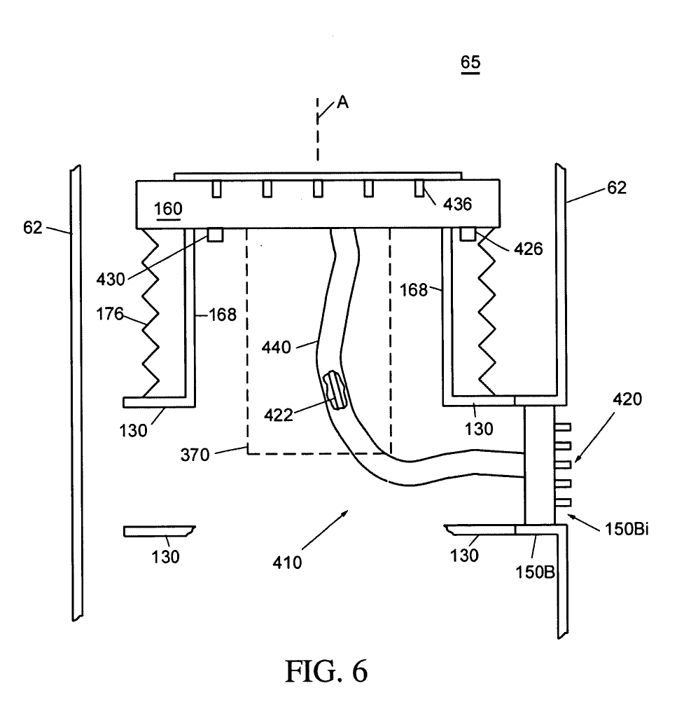

With reference now to FIG. 6, utilities support arm 150B is now described. Utilities support arm has an input end 150Bi and is hollow so that a utilities supply system 410 of the present invention can communicate with chuck assembly 110 through this supply arm. Utilities supply system 410 includes at input end 150Bi one or more input/output ports 420 that connect to respective devices located within chuck assembly 110 via utility lines 422. The input/output ports 420 and the corresponding devices typically include the following: a helium port for a helium line used to supply helium for the wafer 116 back-side to improve the gas gap conductance and in turn improve the wafer-to-chuck heat transfer; a nitrogen port for a nitrogen line for purging the inner chuck cavity and variable capacitor seals to reduce condensation, a thermocouple port for electrically connecting a thermocouple (not shown) within chuck assembly 100 to main control system 300, for monitoring the chuck temperature; a current monitor port for electrically connecting a current monitor 426 electrically connected to workpiece support member 160 for monitoring the RF current to the chuck electrode; a voltage probe port for electrically connecting a voltage probe 430 electrically connected to workpiece support member 160 for monitoring the chuck electrode voltage; an electrostatic clamp port for electrically connecting an electrostatic clamp (not shown) in operable communication with workpiece support member 160 for electrostatically securing workpiece 116 to upper surface 164 of support member 160; and a pneumatic push pin supply port for pneumatically connecting pneumatic push pins 436 located in upper surface 164 of workpiece support member 160, for lifting workpiece 116 from the support member upper surface.

The various utility lines 422 leading from ports 420 to the respective devices may be gathered into a flexible cable 440 so that the lines occupy as small a volume within chuck assembly 100 as possible. Flexible cable 440 is designed to flex to accommodate the vertical movement of workpiece support member 160.

With reference now to FIG. 7, mechanical support arm 150C is hollow and is used to provide a pathway for the mechanical connection between vertical drive motor 170 and workpiece support member 160 as part of a drive mechanism 500.

Drive mechanism 500 includes drive motor 170 having a drive shaft 508 extending therefrom, with the distal end of the shaft having a first beveled gear 512. Mechanism 500 further includes two vertical translation screws 520 and 522 each having respective threaded upper portions 530 and 532. Screws 520 and 522, which can be considered as the aforementioned vertical translation members 168 (FIG. 1), are arranged parallel to the y-axis and central axis A and are threadedly engaged at their respective upper portions 530 and 532 with respective elongate threaded nuts 536 and 538 that depend from lower surface 162 of workpiece support member 160. At distal ends of translation screws 520 and 522 are respective sprockets 560 and 562 engagedly connected by a chain 566. Attached to sprocket 562 and depending a short distance therefrom is a second beveled gear 570. Vertical translation screw 522 is arranged so that second beveled gear 570 matingly engages first beveled gear 512 of drive shaft 508.

In operation, to vertically position workpiece support member 160 within interior region 65 of chamber 60, main control system 300 transmits an electronic signal to drive motor 170, thereby initiating the rotation of drive shaft 508. Position sensors (not shown) provide feedback signals to main control system 300. This rotation causes the rotation of sprocket 562 and thus the rotation of vertical translation screw 522 via the engagement of first and second beveled gears 512 and 570. Because of the coupling between sprockets 560 and 562 via chain 566, vertical translation screws 520 and 522 rotate in synchrony. The threaded engagement of translation screws 520 and 522 with corresponding threaded nuts 530 and 532 causes workpiece support member 160 to move vertically upward (i.e., toward upper wall 64) or vertically downward, depending on the direction of rotation of drive shaft 508. In alternate embodiments, other drive mechanisms can be used.

Since numerous modifications and changes to the embodiments described above will readily occur to those of ordinary skill in the art, it is not desired to limit the invention to the exact construction and operation illustrated and described. Accordingly, all suitable modifications and equivalents should be considered as falling within the spirit and scope of the invention.

What is claimed is:

1. A vertically translatable chuck assembly for supporting a workpiece at different locations within a plasma reactor chamber having sidewalls surrounding an interior region, comprising:
a chuck base having a perimeter, an upper surface and lower surface;
at least one support arm extending outwardly from said perimeter to said sidewalls so as to support said chuck base within said interior region;
a workpiece support member having a lower surface and an upper surface capable of supporting the workpiece, arranged above said chuck base upper surface; and
one or more vertical translation members arranged between and operatively connecting said chuck base and said workpiece support member for supporting and vertically translating said workpiece support member relative to said chuck base.

2. An assembly according to claim 1, wherein one or more of said at least one support arm is adapted to provide mechanical, fluid, electrical and/or pneumatic communication from outside the plasma reactor chamber to said chuck assembly.

3. An assembly according to claim 1, further including a match network having a first variable capacitor mounted to said workpiece support member lower surface so as to be in direct electrical communication therewith.

4. An assembly according to claim 3, wherein said match network further includes a first inductor arranged adjacent said first variable capacitor within the chuck assembly between said chuck base upper surface and said workpiece support member lower surface.

5. An assembly according to claim 4, wherein said match network further includes a second variable capacitor arranged within the chuck assembly between said chuck base upper surface and said workpiece support member lower surface.

6. An assembly according to claim 4, wherein said match network further includes a second variable capacitor and a second inductor, each located outside of the chuck assembly and electrically connected to said first inductor through one of said support arms.

7. An assembly according to claim 1, further including one or more utility ports and corresponding one or more utility lines connected to said one or more ports and passing through one of said support arms so as to provide one or more utilities to said chuck assembly.

8. An assembly according to claim 7, wherein said one or more utility ports includes at least one of: a helium port, a nitrogen port, a thermocouple port, a current monitor port, a pneumatic push-pin supply port, an electrostatic clamp port and a voltage probe port.

9. An assembly according to claim 7, wherein said utility lines are gathered into a flexible cable designed to accommodate vertical translation of said workpiece support member relative to said chuck base.

10. An assembly according to claim 1, further including mechanical means for vertically translating said workpiece support member relative to said chuck base.

11. An assembly according to claim 10, further including a vertical drive motor external to the plasma reactor chamber and in operable communication with said vertical translation members through one said support arm.

12. An assembly according to claim 1, wherein said workpiece support member includes one or more cavities adapted to receive and circulate cooling fluid within said workpiece support member, and further including a cooling system arranged external to the plasma reactor chamber and in fluid communication with said one or more cavities via one or more cooling fluid lines passing through one said support arm.

13. An assembly according to claim 1, further including bellows connected at one end to lower surface of the workpiece support member, and at the opposite end upper surface of the chuck base.

14. An assembly according to claim 1, further including a control system coupled to the vertical translation members for controlling their vertical translation.

15. A plasma reactor system for processing a workpiece, comprising:
a plasma reactor chamber having a central axis and sidewalls surrounding an interior region capable of supporting a plasma in an upper part of the interior region;
a chuck assembly arranged adjacent said upper part of the interior region and along the central axis, the chuck assembly including:
a chuck base having a perimeter, an upper surface and lower surface,
at least one support arm extending outwardly from said perimeter to said sidewalls so as to support said chuck base within said interior region,
a workpiece support member having a lower surface and an upper surface capable of supporting the workpiece, arranged above the chuck base upper surface, and
one or more vertical translation members arranged between and operatively connecting said chuck base and said workpiece support member for supporting and vertically translating said workpiece support member relative to said chuck base; and
a vacuum pump system arranged adjacent said chuck assembly opposite said upper part and along the central axis.

16. A system according to claim 15, wherein said vacuum system includes a vacuum pump and a gate valve arranged between the chuck assembly and the vacuum pump.

17. A system according to 15, further including a workpiece load chamber with a sealable door in communication with the interior region and arranged so that a workpiece can be placed into the interior region and onto the workpiece support member.

18. A system according to claim 17, further including a chuck match network, wherein a portion of said chuck match network resides between said workpiece support member and said chuck base.

19. A system according to claim 18, further including an RF power supply connected to said match network through said support arm.

20. A system according to claim 18, further including a cooling system in fluid communication with said workpiece support member via one or more cooling lines through said support arm.

21. A system according to claim 20, further including a gas supply system in pneumatic communication with said interior region, for supplying gas for forming the plasma.

22. A system according to claim 21, further including a workpiece handling system in operable communication with said load chamber, for transporting wafers to and from said workpiece support member through the load chamber.

23. A system according to claim 21, further including a plasma source generator arranged around the outside of the plasma reactor chamber so as to surround the upper part of the interior region.

24. A system according to claim 23, further including a control system in electrical communication with said plasma source generator, said gas supply system, said cooling system, said RF power supply, and said vacuum system, for controlling the operation of the plasma reactor system.

25. A system according to claim 23, further including a control system in electrical communication with said vertical translation members for controlling their vertical translation.

26. A match network for use with a plasma reactor system having a plasma reactor chamber and a vertically translatable chuck assembly having a workpiece support member with a lower surface, comprising:
a first variable capacitor mounted to said workpiece support member lower surface so as to be in direct electrical contact therewith; and
a first inductor arranged adjacent said first variable capacitor within the chuck assembly and in electrical communication with said first variable capacitor.

27. A match network according to claim 26, wherein the match network further includes a second variable capacitor arranged within the chuck assembly.

28. A match network according to claim 26, wherein said match network further includes a second variable capacitor and a second inductor, each located outside of the plasma reactor chamber and electrically connected to said first inductor.

29. A method of providing a low impedance path between an RF power supply and a workpiece support member with upper and lower surfaces, serving as a chuck electrode in a plasma reactor system capable of supporting a plasma with an associated impedance load adjacent the workpiece support member upper surface, comprising:
providing a match network having a first variable capacitor between the RF power supply and the workpiece support member, including the step of mounting said first variable capacitor to said workpiece support member lower surface so as to be in direct electrical contact therewith; and
tuning said match network to match the impedance load of the plasma so as to minimize the impedance between the RF power supply and the workpiece support member.

30. A method according to claim 29, further including:
initiating the flow of RF power from the power supply through the match network to the workpiece support member.

31. A method according to claim 29, wherein the providing further includes:
providing a first inductor adjacent and proximate said first variable capacitor and electrically connected thereto.

32. A method according to claim 31, wherein the providing further includes:
providing a second inductor removed from said first inductor but electrically connected thereto so that said second inductor is not proximate said chuck workpiece support member lower surface.

33. A method according to claim 31, wherein the providing further includes:
providing a second variable capacitor electrically connected to said first inductor and arranged adjacent said first inductor so as to be proximate chuck workpiece support member lower surface.

34. A method of providing for uniform, substantially axially symmetric flow of plasma gas over a workpiece in a plasma reactor chamber having a central axis and capable of containing a plasma in an upper interior region of the chamber, comprising:
supporting a chuck assembly within the reactor chamber with a plurality of support arms such that gas can flow around the chuck assembly from the upper interior region;
arranging a vacuum pump system along the central axis adjacent the chuck assembly opposite the upper interior region;
providing the workpiece to the chuck assembly such that the workpiece is supported adjacent the upper interior region;
flowing gas into the upper interior region and forming a plasma in the upper interior region; and
activating the vacuum pump system so as to draw gas from the upper interior region over the workpiece and into the vacuum pump system.

35. A plasma reactor system for processing a workpiece, comprising:
a plasma reactor chamber having a central axis and sidewalls surrounding an interior region capable of supporting a plasma in an upper part of the interior region;
a chuck assembly arranged adjacent said upper part of the interior region and along the central axis, the chuck assembly including:
a chuck base having a perimeter, an upper surface and lower surface,
at least one support arm extending outwardly from said perimeter to said sidewalls so as to support said chuck base within said interior region,
a workpiece support member having a lower surface and an upper surface capable of supporting the workpiece, removably arranged above the chuck base upper surface, and
one or more vertical translation members arranged between and operatively connecting said chuck base and said workpiece support member for supporting and vertically translating said workpiece support member relative to said chuck base; and
a vacuum pump system arranged adjacent said chuck assembly opposite said upper part and along the central axis.

36. A plasma reactor system for processing a workpiece, comprising:
a plasma reactor chamber having a central axis and sidewalls surrounding an interior region capable of supporting a plasma in an upper part of the interior region;
a chuck assembly removably mounted within said chamber, arranged adjacent said upper part of the interior region and along the central axis, the chuck assembly including:
a chuck base having a perimeter, an upper surface and lower surface,
at least one support arm extending outwardly from said perimeter to said sidewalls so as to support said chuck base within said interior region,
a workpiece support member having a lower surface and an upper surface capable of supporting the workpiece, arranged above the chuck base upper surface, and
one or more vertical translation members arranged between and operatively connecting said chuck base and said workpiece support member for supporting and vertically translating said workpiece support member relative to said chuck base; and
a vacuum pump system arranged adjacent said chuck assembly opposite said upper part and along the central axis.
